(19) United States
(12) Patent Application Publication
(10) Pub. No.: US 2026/0344369 A1
(43) Pub. Date: Oct. 29, 2026

(54) SEMICONDUCTOR DEVICE AND METHOD FOR DETECTING ALIGNMENT ACCURACY IN THE SEMICONDUCTOR DEVICE

(71) Applicant: Yangtze Memory Technologies Co., Ltd., Wuhan (CN)

(72) Inventors: Qijun Wang, Wuhan (CN); Xiaolong Hu, Wuhan (CN); Jiawen Wang, Wuhan (CN); Yang Li, Wuhan (CN)

(21) Appl. No.: 19/321,851

(22) Filed: Sep. 8, 2025

Related U.S. Application Data
(63) Continuation of application No. PCT/CN2025/091123, filed on Apr. 25, 2025.

(51) Int. Cl. H10P 74/00; H10P 74/20; H10W 42/00; H10W 90/00

(52) U.S. Cl. CPC H10P 74/277; H10P 74/207; H10W 42/00; H10W 90/792

(57) ABSTRACT

Examples of present disclosure relate to semiconductor devices, comprising a first semiconductor structure and a second semiconductor structure stacked on the first semiconductor structure in a stacking direction and bonded thereto. The semiconductor device further comprises a sealing structure surrounding the first and the second semiconductor structures. The semiconductor device comprises a resistance chain structure located on an inner side of the sealing structure, wherein the resistance chain structure extends in the first and second semiconductor structures alternatingly and comprises a plurality of first resistance pads in the first semiconductor structure and a plurality of second resistance pads in the second semiconductor structure, the plurality of second resistance pads being bonded to the plurality of first resistance pads, respectively.

### CROSS-REFERENCE TO RELATED APPLICATIONS

This application is a continuation of International Application No. PCT/CN2025/091123, filed on Apr. 25, 2025, which is hereby incorporated by reference in its entirety.

### TECHNICAL FIELD

The present disclosure generally relates to semiconductor technology, and more particularly, to a semiconductor device including a resistance chain structure and a method for detecting an alignment accuracy in the semiconductor device.

### BACKGROUND

With the increasing demands for storage capacity and performance, three-dimensional (3D) memory devices, such as 3D NAND flash memory, 3D dynamic random access memory (DRAM) and high-bandwidth memory (HBM), have been widely used. In order to optimize performance of 3D memory devices, a bonding technology has also been proposed. In an example, two chips are separately formed and then bonded together using wafer bonding technology.

However, the chips may be bonded without appropriate alignment. During the bonding process, various factors may lead to alignment deviations. These factors include, but not limited to, differences in wafer deformation, alignment marks and equipment accuracy, vacuum and pressure control, and thermal expansion and contraction, etc. These misalignments may result in anomalies, for example, voids at the bonding interface, which may cause migration phenomenon and affect the reliability and lifespan of memory devices.

### SUMMARY

Various example embodiments of the present disclosure provide a semiconductor device, an electronic device including the same, a method for manufacturing the same and a method for detecting an alignment accuracy in the semiconductor device, to improve the alignment detection and the reliability of the semiconductor device and to reduce the cost.

In a first aspect of the present disclosure, example embodiments of the present disclosure provide a semiconductor device. The semiconductor device includes a first semiconductor structure and a second semiconductor device stacked on the first semiconductor structure in a stacking direction and bonded thereto. The semiconductor device further includes a sealing structure surrounding the first and the second semiconductor structures. In addition, the semiconductor device includes a resistance chain structure located on an inner side of the sealing structure. The resistance chain structure extends in the first and second semiconductor structures alternatingly and includes a plurality of first resistance pads in the first semiconductor structure and a plurality of second resistance pads in the second semiconductor structure. The plurality of second resistance pads are bonded to the plurality of first resistance pads respectively.

In some examples, the semiconductor device also includes a plurality of memory cells located on an inner side of the resistance chain structure.

In some examples, the sealing structure includes an isolation structure.

In some examples, the semiconductor device further includes a test structure located between the resistance chain structure and the plurality of memory cells.

In a second aspect of the present disclosure, example embodiments of the present disclosure provide another semiconductor device. The semiconductor device includes a first semiconductor structure and a second semiconductor device stacked on the first semiconductor structure in a stacking direction and bonded thereto. The semiconductor device further includes a plurality of memory cells. In addition, the semiconductor device also includes a resistance chain structure located on an outer side of the plurality of memory cells. The resistance chain structure extends in the first and second semiconductor structures alternatingly and includes a plurality of first resistance pads in the first semiconductor structure and a plurality of second resistance pads in the second semiconductor structure. The plurality of second resistance pads are bonded to the plurality of first resistance pads respectively.

In some examples, in a cross section perpendicular to the stacking direction, the resistance chain structure completely or partially surrounds the plurality of memory cells.

In some examples, the resistance chain structure is also located at a corner region of the semiconductor device. In some examples, the corner region extends in a direction angled with respect to the transverse directions.

In some examples, the resistance chain structure includes a plurality of resistance strings, and the plurality of resistance strings in the resistance chain structure are serially interconnected. The resistance strings are electrically operable structures. In other words, the resistance strings may be part of a current flow path of a circuit. In some examples, at least one of the plurality of resistance string includes a pair of a first resistance pad of the plurality of first resistance pads and a second resistance pad of the plurality of second resistance pads bonded to the first resistance pad.

In some examples, the resistance string further includes first interconnections arranged in the first semiconductor structure and connected to the first resistance pad. The resistance string further includes second interconnections arranged in the second semiconductor structure and connected to the second resistance pad.

In some examples, the first interconnections are arranged in a first interconnect layer of the first semiconductor structure. The second interconnections are arranged in a second interconnect layer of the second semiconductor structure.

In some examples, the resistance chain structure includes first connecting lines interconnecting two adjacent resistance strings in the first semiconductor structure. The resistance chain structure further includes second connecting lines interconnecting two adjacent resistance strings in the second semiconductor structure. The second connecting lines are offset relative to the first connecting lines in a transverse direction perpendicular to the stacking direction.

In some examples, a first connecting line connects a first resistance string with a second resistance string adjacent to the first resistance string. A second connecting line connects the second resistance string with a third resistance string adjacent to the second resistance string. The second connecting line is offset relative to the first connecting line in the transverse direction.

In some examples, the second semiconductor structure is bonded to the first semiconductor structure via a plurality of pairs of bonding pads.

In some examples, at least one of the plurality of first resistance pads or the plurality of second resistance pads has a dimension in a cross section perpendicular to the stacking direction that is smaller than that of a bonding pad of the plurality of pairs of bonding pads. In some examples, the dimension in a transverse direction of both the first and the second resistance pads is smaller than that of the bonding pads.

In some examples, at least one of the plurality of first resistance pads or the plurality of second resistance pads has a via with a dimension in the stacking direction which is smaller than that of a bonding pad of the plurality of pairs of bonding pads. In some example, the dimension in the stacking direction of both the first and the second resistance pads are smaller than the bonding pads.

In some examples, the first semiconductor structure and the second semiconductor structure are Dynamic Random Access Memory.

In some examples, the first semiconductor structure and the second semiconductor structure are NAND Flash Memory.

In some examples, one of the first and the second semiconductor structures includes a peripheral circuit, and the other of the first and the second semiconductor structures includes a memory array structure.

In some examples, the resistance chain structure includes a first and a second detection pads configured to measure an electrical parameter of the resistance chain structure. The first and second detection pads are located on a side of the first or second semiconductor structure away from each other.

In some examples, a first end of one resistance string is connected with the first detection pad and a second end of the one resistance string opposite to the first end is connected with a first or a second connecting line. In some examples, a first end of another resistance string is connected with the second detection pad and a second end of the another resistance string opposite to the first end is connected with a first or a second connecting line.

In some examples, at least one of the first resistance pad or the second resistance pad includes at least one via filled with a metallic conductive material.

In some examples, the plurality of first resistance pads are arranged in a first bonding layer of the first semiconductor structure. In some examples, the plurality of second resistance pads are arranged in a second bonding layer of the second semiconductor structure.

In a second aspect of the present disclosure, example embodiments of the present disclosure provide an electronic device. The electronic device includes any of the semiconductor devices as described above.

In a third aspect of the present disclosure, example embodiments of the present disclosure provide a method for manufacturing any of the semiconductor devices as described above. The method includes forming a first semiconductor structure including a plurality of first resistance pads. The method includes forming a second semiconductor structure including a plurality of second resistance pads. The method further includes stacking and bonding the second semiconductor structure on the first semiconductor structure in a stacking direction, during which the plurality of second resistance pads are bonded to the plurality of first resistance pads respectively.

In some examples, the method includes forming a sealing structure surrounding the first and the second semiconductor structures. During the bonding, a resistance chain structure is formed and located on an inner side of the sealing structure.

In some examples, the method includes forming a plurality of memory cells. During the bonding of the first and the second semiconductor structures, a resistance chain structure is formed and located on an outer side of the plurality of memory cells.

The resistance chain structure extends in the first and the second semiconductor structures alternatingly and includes a plurality of resistance strings. The plurality of resistance strings in the resistance chain structure are serially interconnected. Each of the plurality of resistance string includes a pair of a first resistance pad of the plurality of first resistance pads and a second resistance pad of the plurality of second resistance pads bonded to the first resistance pad.

In some examples, forming a first semiconductor structure includes forming the first interconnections connected to the plurality of the first resistance pad. In some examples, forming a second semiconductor structure includes forming second interconnections connected to the plurality of the second resistance pad. The resistance string includes the first interconnections and the second interconnections.

In some examples, forming a first semiconductor structure includes forming the first connecting lines in the first semiconductor structure. The first connecting lines interconnect two adjacent resistance strings in the first semiconductor structure. In some examples, forming a second semiconductor structure includes forming second connecting lines in the second semiconductor structure. The second connecting lines interconnect two adjacent resistance strings in the second semiconductor structure. The second connecting lines are offset relative to the first connecting lines in a transverse direction perpendicular to the stacking direction, respectively.

In some examples, forming a first semiconductor structure includes forming a first and a second detection pads in the first semiconductor structure. In other examples, forming a second semiconductor includes forming a first and a second detection pads in the second semiconductor structure. The first and the second detection pads are configured to measure an electrical parameter of the resistance chain structure.

In a fourth aspect of the present disclosure, example embodiments of the present disclosure provide a method for detecting an alignment accuracy in a semiconductor device. The semiconductor device includes a first semiconductor structure and a second semiconductor structure stacked on the first semiconductor in a stacking direction and bonded thereto. The method includes forming a resistance chain structure. The resistance chain structure extends in the first and the second semiconductor structures alternatingly and includes a plurality of first resistance pads in the first semiconductor structure and a plurality of second resistance pads in the second semiconductor structure. The plurality of second resistance pads is bonded to the plurality of first resistance pads respectively. The resistance chain structure further includes a first and a second detection pads configured to measure an electrical parameter of the resistance chain structure. The method includes connecting at least two test leads to the first and the second detection pads of the resistance chain structure and measuring the electrical parameter of the resistance chain structure. The method further includes determining an alignment accuracy of the first and the second semiconductor structures based on the measured electrical parameter.

In some examples, the method includes establishing a correlation between the electrical parameter and the alignment accuracy of the first and the second semiconductor structures. In some examples, the method further includes determining the alignment accuracy based on the correlation and the measured electrical parameter.

In some examples, the method includes determining a threshold of the electrical parameter corresponding to an acceptable alignment accuracy and comparing the measured electrical parameter to the threshold to determine whether the alignment accuracy is acceptable.

In some examples, the semiconductor device includes a plurality of memory cells. The method includes forming a resistance chain structure located on an outer side of the plurality of memory cells, with a similar construction as mentioned in the above. The method further includes connecting at least two test leads to the first and the second detection pads of the resistance chain structure and measuring the electrical parameter of the resistance chain structure. The method further includes determining an alignment accuracy of the first and the second semiconductor structures based on the measured electrical parameter.

### DESCRIPTION OF DRAWINGS

Through the following detailed descriptions with reference to the accompanying drawings, the above and other objectives, features, and advantages of the example embodiments disclosed herein will become more comprehensible. In the drawings, several example embodiments disclosed herein will be illustrated in an example and in a non-limiting manner.

FIG. 1 illustrates a schematic view of a semiconductor device in accordance with an example of the present disclosure;

FIG. 2 illustrates a schematic view of a semiconductor device in accordance with an example of the present disclosure with an example resistance chain structure shown;

FIG. 3 illustrates a schematic view of a semiconductor device in accordance with an example of the present disclosure with another example resistance chain structure shown;

FIG. 4 illustrates a simplified and schematic sectional view of a portion of a semiconductor device with an example resistance chain structure in accordance with an example of the present disclosure;

FIG. 5 illustrates a schematic sectional view of a semiconductor device with an example resistance chain structure in accordance with an example of the present disclosure;

FIG. 6 illustrates a schematic top view of a semiconductor device in accordance with an example of the present disclosure at the bonding interface, a portion of which is shown enlarged;

FIG. 7 illustrates a schematic top view of a semiconductor device in accordance with another example of the present disclosure at the bonding interface, a portion of which is shown enlarged;

FIGS. 8-10 illustrate a schematic top view of three example arrangements of the resistance chain structure in a semiconductor device in accordance with another example of the present disclosure;

FIGS. 11 illustrates a schematic sectional view of a resistance chain structure in accordance with an example of the present disclosure;

FIGS. 12 illustrates a schematic sectional view of a resistance chain structure in accordance with another example of the present disclosure;

FIG. 13 illustrates a schematic sectional view of a resistance string in accordance with an example of the present disclosure;

FIG. 14 illustrates a schematic sectional view of a first and a second bonding pads in accordance with an example of the present disclosure;

FIG. 15 illustrates a schematic sectional view of a first and a second bonding pads in accordance with another example of the present disclosure;

FIG. 16 illustrates a schematic flowchart of a method for manufacturing a semiconductor device in accordance with an example of the present disclosure;

FIG. 17 illustrates a schematic flowchart of a method for detecting an alignment accuracy in a semiconductor device in accordance with an example of the present disclosure; and

FIG. 18 is a schematic diagram of a memory system illustrated according to an example of the present disclosure.

Throughout the drawings, the same or similar reference symbols are used to indicate the same or similar elements.

### DETAILED DESCRIPTION

Although specific configurations and arrangements are discussed, it should be understood that this is done for illustrative purposes only. A person skilled in the pertinent art will recognize that other configurations and arrangements may be used without departing from the spirit and scope of the present disclosure. It will be apparent to a person skilled in the pertinent art that the present disclosure may also be employed in a variety of other applications.

It is noted that references in the specification to “one embodiment,” “an embodiment,” “an example embodiment,” “some embodiments,” “an example,” etc., indicate that the embodiment described may include a particular feature, structure, or characteristic, but every embodiment may not necessarily include the particular feature, structure, or characteristic. Moreover, such phrases do not necessarily refer to the same example. Further, when a particular feature, structure, or characteristic is described in connection with an example, it would be within the knowledge of a person skilled in the pertinent art to affect such feature, structure, or characteristic in connection with other examples whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer there between. Moreover, “above” or “over” not only means “above” or “over” something, but may also include the meaning it is “above” or “over” something with no intermediate feature or layer there between (e.g., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or process step in addition to the orientation depicted in the figures. The device may be otherwise oriented (rotated 90 degrees or at other orientations) and the spatially relative descriptors used herein may likewise be interpreted accordingly.

As used herein, the term “layer” refers to a material portion including a region with a thickness. A layer may extend over the entirety of an underlying or overlying structure, or may have an extent less than the extent of an underlying or overlying structure. A layer may extend horizontally, vertically, and/or along a tapered surface. A layer may include multiple layers. For example, an interconnect layer may include one or more conductive and contact layers (in which contacts, interconnect lines, and/or vertical interconnect accesses (VIAs) are formed) and one or more dielectric layers.

In the present disclosure, the term “horizontal/horizontally/transverse” means nominally parallel to a lateral surface of a substrate. In the present disclosure, the term “each” may mean “each of all” or “each of a subset.”

As used herein, a “wafer” is a piece of semiconductor material into which and/or on which semiconductor devices are built, and which may undergo various processes before being diced into dies.

Although terms such as first, second, third, etc., may be used to describe diverse constituent elements, such constituent elements are not limited by the terms. The terms are used only to discriminate a constituent element from other constituent elements in the specification. These terms do not intend to sort an order of the constituent elements and/or an order of the manufacturing process of the constituent elements.

In the drawings, an x-y-z orthogonal coordinate system is used for convenience of description, in which a z-direction defines a stacking direction along which the first and the second semiconductor structures are stacked. An x-direction and a y-direction are orthogonal to the z-direction, also referred as transverse directions.

Examples of the disclosure relate to electronic devices including a semiconductor device, such as a 3D memory device. Examples of such electronic devices may be mobile phones, computers, tablets, smart watches, cameras, TVs, wearable devices, automotive electronics, internet of things (IoT) devices, home appliances, servers and data centers, a virtual reality (VR) device, an argument reality (AR) device, or any other suitable electronic devices having storage therein. Examples of the semiconductor device may be wafer, chip, die or package thereof, etc.

Example of the electronic devices may include a host and a memory system having one or more semiconductor devices and a memory controller. Host may be a processor of an electronic device, such as a central processing unit (CPU), or a system-on-chip (SoC), such as an application processor (AP). Host may be configured to send or receive the data to or from semiconductor devices. Semiconductor device may be any semiconductor devices disclosed herein, such as a 3D memory device. In some examples, each semiconductor device includes one or more memory cell arrays and one or more peripheral circuits of the memory cell arrays. Memory controller is coupled to semiconductor device and host, and is configured to control semiconductor device.

FIG. 1 illustrates a schematic view of a semiconductor device 100 in accordance with an example of the present disclosure. Referring to FIG. 1, the semiconductor device 100 includes a first semiconductor structure 110 and a second semiconductor structure 120 stacked thereon along the z-direction. The second semiconductor structure 120 is bonded to the first semiconductor structure 110 at a bonding interface 101 by means of the bonding technology, such as direct bonding, anodic bonding, eutectic bonding, adhesive bonding, and hybrid bonding, etc.

In an example of a HBM stack, both the first and the second semiconductor structures 110, 120 may be a DRAM, for example, two adjacent DRAM in the HBM stack. In another example of a HBM stack, one of the first and the second semiconductor structures 110, 120 may be a DRAM in the HBM stack, and the other one may be a base die in the HBM stack. In some examples, the base die serves as the logic control layer that manages data communication between the HBM stack and a processor (e.g., Graphics Processing Unit or Central Processing Unit).

In some examples, a semiconductor device could include a NAND stack, e.g., a stack of NAND flash memories. In another example, both the first and the second semiconductor structures 110, 120 are NAND flash memory. In an example, one of the first and the second semiconductor structures may be NAND flash memory and the other may be base die. In some examples, the base die serves as the logic control layer that manages data communication between the NAND stack and a processor (e.g., Graphics Processing Unit or Central Processing Unit). In another example, the first semiconductor structure 110 includes a peripheral device, and the second semiconductor structure 120 includes a memory array structure (such as a memory array chip), or vice versa. In an example, the peripheral device is bonded to the memory array structure by hybrid bonding. Hybrid bonding hereinafter refers to a bonding technique that combines a direct-bonding technique and a metal-interconnect technique. It involves depositing a thin layer of dielectric material (e.g., SiO₂ or SiCN) on the surface to be bonded, and then fabricating pads (e.g., copper) and through-silicon vias (TSVs). Subsequently, the pads of two chips are directly pressed together to form an electrical connection.

In some examples, the memory array structure is a NAND Flash memory device, in which memory cells are provided in the form of an array of NAND memory strings in a memory array device layer. In some examples, each NAND memory string extends vertically (e.g., z-direction) through a plurality of pairs each including a conductor layer and a dielectric layer (referred to as “conductor/dielectric layer pairs”). The stacked conductor/dielectric layer pairs are collectively referred to herein as a “memory stack” in the memory array device layer. Each NAND memory string may include a semiconductor channel and a composite dielectric layer (also known as a “memory film”) including a tunneling layer, a storage layer (also known as a “charge trap/storage layer”), and a blocking layer.

The peripheral device may include any suitable digital, analog, and/or mixed-signal peripheral circuits used for facilitating the operation of 3D semiconductor device. For example, the peripheral device may include one or more of a page buffer, a decoder (e.g., a row decoder and a column decoder), a driver, a charge pump, a current or voltage reference, or any active or passive components of the circuits (e.g., transistors, diodes, resistors, or capacitors). In some examples, the peripheral device is formed using complementary metal-oxide-semiconductor (CMOS) technology, and the peripheral device may be referred to as a “CMOS structure” or a “CMOS chip.”

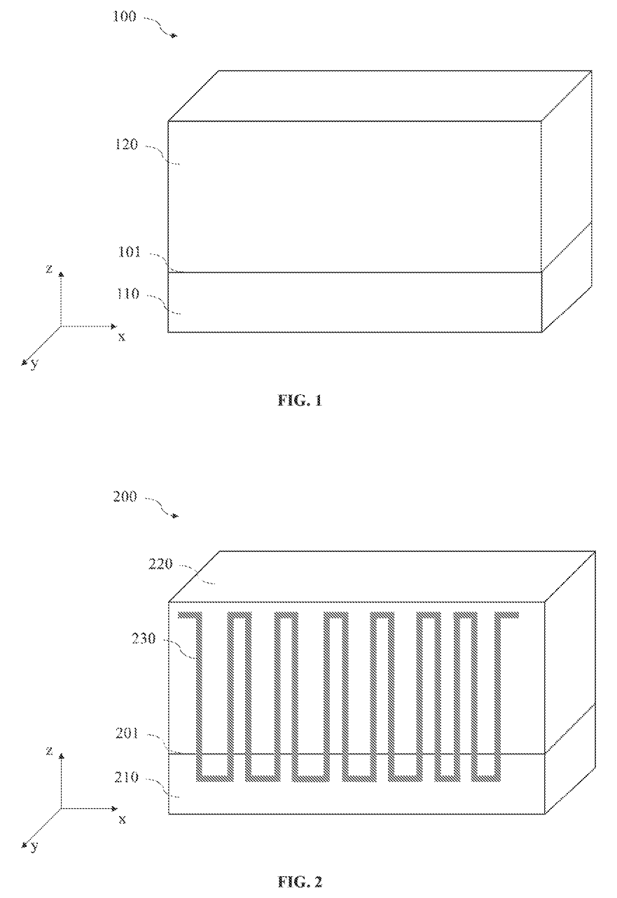

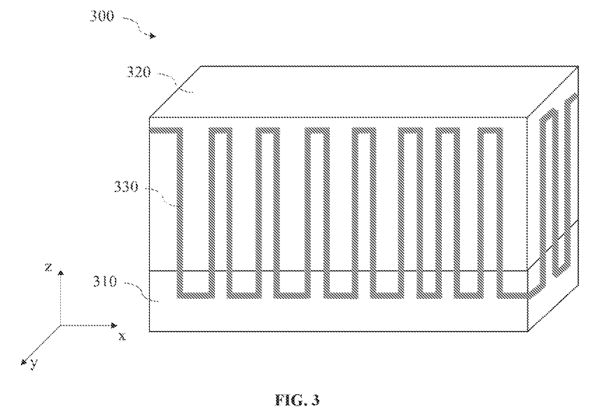

FIG. 2 illustrates a schematic view of a semiconductor device 200 according to an example embodiment. The semiconductor device 200 includes a resistance chain structure 230. The resistance chain structure 230 is shown to be located on one side of the semiconductor device 200 and adjacent to an edge thereof, as may be seen in the following figures.

Alignment-related defects (such as bubble defects), e.g., such as those with significant alignment deviations, may occur in the edge areas of the bonded structures. In some related approaches, such as inline overlay measurement process, alignment deviations in these edge areas may be difficult to detect. In some other related detection approaches, alignment abnormalities may be detected when the alignment deviations are significant. After production, the chips or dies typically undergo various testing to sort good or qualified ones. The dies that fail testing are marked and may possibly be unusable. These detection approaches may lead to a large number of usable dies being falsely detected as defective or unqualified, also referred to as being overkilled, and these functional and qualified chips or dies (usable die) may be mistakenly discarded due to inaccurate detection, resulting in waste, unnecessary costs and inefficiency.

The resistance chain structure 230 forms an electrically conductive path for detecting an alignment between the first and the second semiconductor structures 210, 220 after bonding. The electrical performance of the resistance chain structure 230 may be determined in various ways. For example, a voltage may be applied to the resistance chain structure 230, and the current flowing through the resistance chain structure 230 may be measured. With the measured current, the integrity of the resistance chain structure 230 reflecting alignment between the first and second semiconductor structures 210 and 220 may be determined. For example, if the current is greater than a current threshold, the alignment is acceptable. If the alignment is undesirable, for example due to a void or a significant misalignment occurring at the bonding interface, resistance of the resistance chain structure 230 significantly increases, causing the current below than the current threshold. Due to such resistance chain structure, it enables detection of the degree of alignment in each individual semiconductor device and the effective capture of migration risk in the semiconductor device. Moreover, by using such resistance chain structure, alignment accuracy may be increased, and the usable die overkill rate may be significantly reduced.

In the bonding process, the degree of alignment is an important factor affecting the yield. The semiconductor devices with an unacceptable degree of alignment may be discarded. In an example of wafer-to-wafer bonding, in the related approaches, a number of alignment marks are provided in the scribe lines of the wafer for determining the degree of alignment in the wafer, which could not characterize the alignment for the individual dies in the wafer. In other words, the alignment is determined at the wafer level. This may not be able to indicate the performance of the respective dies in the wafer. Furthermore, such related approaches may result in the discarding of dies with acceptable alignment, leading to reduced yield and unnecessary waste. By utilizing the resistance chain structure in the present disclosure, the alignment of degree may be easily determined at the die level, thus improving the yield and avoiding the waste.

As shown, the resistance chain structure 230 includes a first portion in the first semiconductor structure 210 and a second portion in the second semiconductor structure 220. In an example, the first portion may be formed simultaneously with the first semiconductor structure 210. In an example, the second portion may be formed simultaneously with the second semiconductor structure 220. That is to say, the respective layers of the first and the second portions may be formed simultaneously with the corresponding layers of the first and the second semiconductor structures 210, 220. The first portion and the second portion may be bonded together in the same process as the bonding of the first and the second semiconductor structures 210, 220. In this way, the degree of alignment of the first and the second semiconductor structures may be reflected by the resistance chain structure 230.

As shown in FIG. 2, the resistance chain structure 230 extends in the first and second semiconductor structures, alternatingly. In other words, the resistance chain structure 230 extends from the first semiconductor structures 210 through the bonding interface 201 into the second semiconductor structure 220, and returns to the first semiconductor structure 210 through the bonding interface 201, and then repeats in this way. The resistance chain structure 230 thus extends in a path similar to the shape of a square wave. In other examples, the resistance chain structure may be of other shapes, e.g., serpentine shape. It is understood that the word “extend” here is to describe that the shape and/or the structure formed in the device for the purpose of easy understanding, rather than characterizing its motion or movement.

FIG. 3 illustrates a resistance chain structure 330 extending in the first and second semiconductor structures 310, 320, alternatingly. In addition to what is shown in FIG. 2, the resistance chain structure 330 in FIG. 3 further extends to another side of the semiconductor device 300. In an example, the resistance chain structure 330 further extends across any side(s) of the semiconductor device 300, for example, across one side, two sides, three sides, four sides or more. The resistance chain structure 330 provided on each side may be connected or separated.

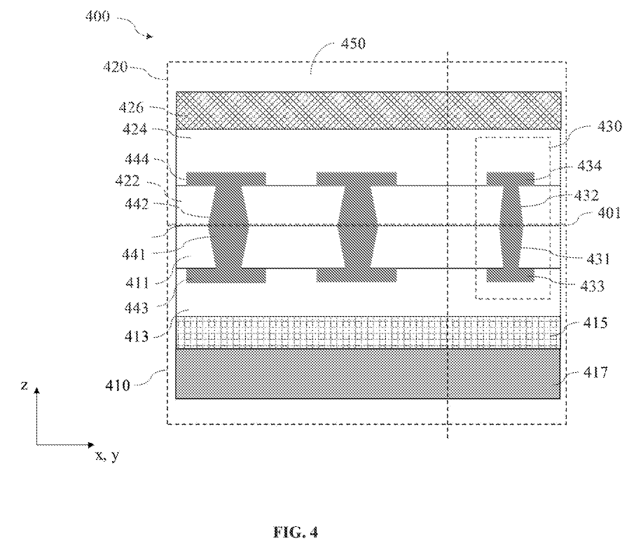

FIG. 4 illustrates a simplified and schematic sectional view of a portion of a semiconductor device 400 along the z-direction. In such examples, the semiconductor device 400 includes a first semiconductor structure 410 and a second semiconductor structure 420 stacked on the first semiconductor structure 410 along the z-direction and bonded thereto at a bonding interface 401. The bonding interface 401 is the place where the first semiconductor structure 410 and the second semiconductor structure 420 are met and bonded. In practice, bonding interface 401 may be a layer with a certain thickness that includes the top surface of first semiconductor structure 410 and the bottom surface of the second semiconductor structure 420. The semiconductor device 400 further includes a main device region 450 in which most of the functional components (such as the stacked memory cells) are provided.

As shown in FIG. 4, the first semiconductor structure 410 includes a first bonding layer 411 and a first interconnect layer 413 below the first bonding layer and a first device layer 415 over a substrate 417. The first interconnect layer 413 may include a plurality of interconnections (also referred to as “contacts”), including vertical interconnect access (via) contacts and lateral interconnect lines. The first interconnect layer may further include one or more interlayer dielectric (ILD) layers (also known as “InterMetal dielectric (IMD) layers”) in which interconnect lines and via contacts may be formed. The second semiconductor structure 420 includes a second bonding layer 422, a second interconnect layer 424 over the second bonding layer and a second device layer 426 over the second interconnect layer.

In the example that the first semiconductor structure 410 is a peripheral device chip, the first device layer 415 may be a peripheral device layer, which may include any suitable digital, analog, and/or mixed-signal peripheral circuits used for facilitating the operation of bonded semiconductor device 400. The first interconnect layer 413 may be a peripheral interconnect layer above the peripheral device layer for transferring electrical signals to and from transistors. The first interconnect layer 413 may include a plurality of interconnections 443, including interconnect lines and via contacts in one or more interlayer dielectric layers. As used herein, the term “interconnections” may broadly include any suitable type of interconnections, such as middle-end-of-line (MEOL) interconnections and back-end-of-line (BEOL) interconnections. The first bonding layer 411 may include a plurality of first bonding pads 441 and dielectrics electrically isolating these bonding pads.

In the example that the second semiconductor structure 420 is a memory array chip, the second device layer 426 may be a memory array device layer, in which a plurality of memory cells are provided. The second interconnect layer 424 may be an array interconnect layer for transferring electrical signals to and from the memory cells. The second interconnect layer 424 may include a plurality of interconnections 444, including interconnect lines and via contacts in one or more interlayer dielectric layers. The second bonding layer 422 may include a plurality of second bonding pads 442 and dielectrics electrically isolating these bonding pads. As shown, the second bonding pads 442 are bonded to the first bonding pads 441, respectively.

Referring to FIG. 4, a portion of an example resistance chain structure 430 is also illustrated. The resistance chain structure 430 is shown to be located adjacent to an edge of the bonded semiconductor device 400. As shown, the resistance chain structure 430 includes a first resistance pad 431 in the first bonding layer 411 of the first semiconductor structure 410 and a second resistance pad 432 in the second bonding layer 422 of the second semiconductor structure 420. The first resistance pad 431 is bonded to the second resistance pad 432 at the bonding interface 401, in the same process as the bonding of the first bonding pad 441 and the second bonding pad 442. In an example, the resistance chain structure 430 further includes a first interconnection 433 in the first interconnect layer 413 and a second interconnection 434 in the second interconnect layer 424. For simplicity, one pair of resistance pads and one pair of bonding pads are described above, but it is not limited to one pair, but may include two, three or more pairs.

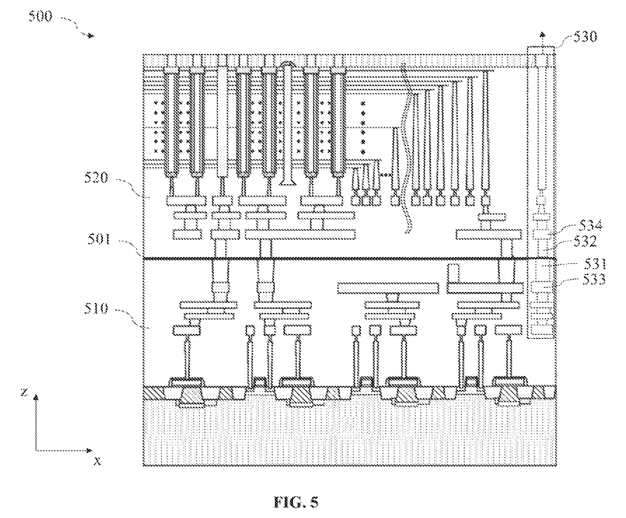

By way of example, FIG. 5 illustrates a more detailed arrangement of a portion of a semiconductor device 500, which shows a sectional view along the z-direction. Similarly, the semiconductor device 500 includes a first semiconductor structure 510 and a second semiconductor structure 520 stacked and bonded thereto at a bonding interface 501. A portion of the example resistance chain structure 530 is shown adjacent to an edge of the semiconductor device 500 for detecting an alignment accuracy of the bonded first and second semiconductor structures 510, 520. The resistance chain structure 530 includes a first resistance pad 531 and a second resistance pad 532. The resistance chain structure 530 further includes a first interconnection 533 connected to the first resistance pad 531 and a second interconnection 534 connected to the second resistance pad 532. The resistance chain structure 530 further includes a first and a second detection pads for the detection of an electrical parameter thereof.

As shown in FIG. 5, the respective layers in the resistance chain structure 530 (e.g., the first and the second bonding layer, the first and the second interconnect layer) may have similar construction as in the main device region, to simplify the processes. In other words, the respective layers of the resistance chain structure may be formed at the same process as the respective layers in the main device region. In some examples, some of the respective layers of the resistance chain structure are formed at the same process as the corresponding layers in the main device region. In some examples, the respective layers of the resistance chain structure are formed separately from the respective layers in the main device region.

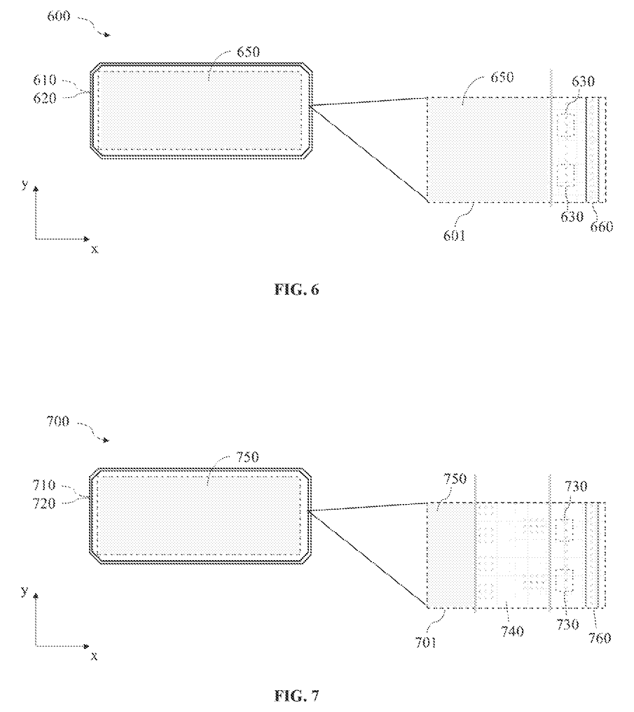

FIG. 6 illustrates a schematic top view of a semiconductor device 600 in an example of the present disclosure at a bonding interface 601, a portion of which is shown enlarged. As shown in FIG. 6, a first semiconductor structure 610 and a second semiconductor structure 620 are already bonded and packaged as a whole. In the enlarged view, the cross section in the x-y plane of a portion of the semiconductor device 600 at the bonding interface 601 is illustrated. As shown, the semiconductor device 600 includes a main device region 650, in which a plurality of memory cells are provided. In the example that the semiconductor device 600 includes a NAND Flash memory device, the memory cells are provided in the form of an array of NAND memory strings. In some examples, each NAND memory string extends vertically through a plurality of pairs each including a conductor layer and a dielectric layer (also referred to as “conductor/dielectric layer pairs”). The stacked conductor/dielectric layer pairs are collectively referred to as a “memory stack.” The conductor layers and dielectric layers in memory stack may stack alternatingly in the vertical direction, e.g., z-direction. Each NAND memory string may include a semiconductor channel and a composite dielectric layer (also known as a “memory film”) including a tunneling layer, a storage layer (also known as a “charge trap/storage layer”), and a blocking layer. Inside the main device region 650, it may have any suitable arrangement in the art. Further, the main device region 650 may also include test circuits or any other suitable circuits.

Referring to FIG. 6, the resistance chain structure 630 may be located on an outer side of the plurality of memory cells, e.g., on an outer side of the main device region 650. As shown in FIG. 6, the points in the dashed boxes indicates the bonded first and second resistance pads.

Furthermore, in some examples, the semiconductor device 600 includes a sealing structure 660 surrounding the first and the second semiconductor structures 610, and 620. The sealing structure 660 is configured to ensure that the semiconductor device 600 is protected from external environmental factors (such as moisture, dust, mechanical stress, etc.) after packaging. The resistance chain structure 630 is located on an inner side of the sealing structure 660. In some examples, the resistance chain structure 630 is located between the main device region 650 and the sealing structure 660.

In an example, the sealing structure 660 is a seal ring for sealing the main device region 650. In an example, the sealing structure 660 includes an isolation structure (not illustrated). Such isolation structure is provided to separate different functional regions or cells, of which its primary purpose is to prevent electrical interference, signal crosstalk, and to ensure reliable data storage and access, etc.

FIG. 7 illustrates another possible arrangement of a semiconductor device 700. The semiconductor device 700 further includes a test structure 740. Test structures are specially designed circuits or regions intended to verify the performance, reliability, and functionality of memory devices during or after the manufacturing process. These test structures 740 are provided to detect manufacturing defects, evaluate electrical characteristics, and optimize process parameters. In some examples, the test structure 740 may be located between the resistance chain structure 730 and the plurality of memory cells in the main device region 750. Generally, the test structure 740 may include one or more test pad(s) and/or one or more test circuit(s). In another example, the test structure 740 may be located an outer side of the resistance chain structure 730. For example, the test structure 740 may be located in the scribe lines.

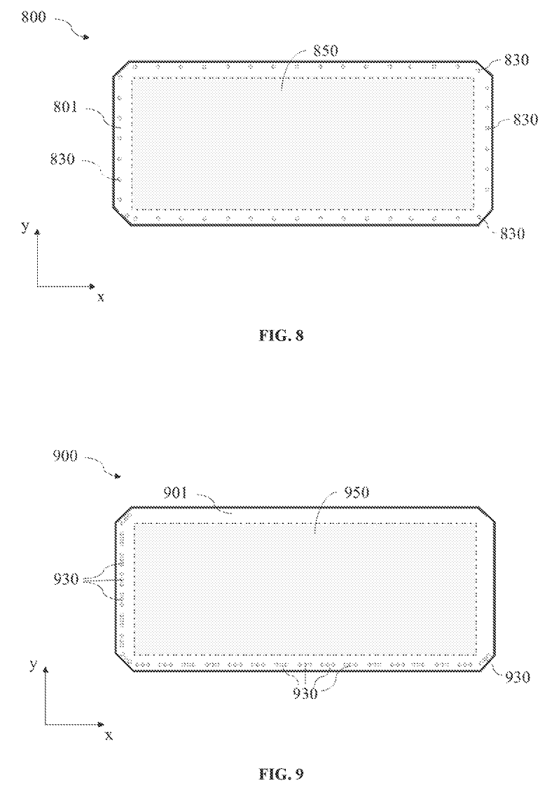

FIG. 8 illustrates a schematic top view of three example arrangements of the resistance chain structure in a semiconductor device 800 at a bonding interface. Referring to FIG. 8, the cross section in the x-y plane of the semiconductor device 800 at the bonding interface 801 is illustrated. As shown, the resistance chain structure 830 is located outside of the main device region 850. In the cross section perpendicular to the stacking direction (e.g., z-direction), the resistance chain structure 830 completely surrounds the plurality of memory cells, e.g., the main device region 850. In other words, the resistance chain structure 830 extends over the entire circumference of the semiconductor device 800 in this cross section. As shown, in some examples, the circles indicating a pair of the first and the second resistance pads at the bonding interface 801 are distributed uniformly over the entire circumference of the semiconductor device 800 in this cross section. In this way, the resistance chain structure 830 could allow more precise detection of the degree of alignment across the entire semiconductor device 800.

FIG. 9 illustrates another example arrangement of the resistance chain structure 930 in a semiconductor device 900 at the bonding interface 901. As shown, in the cross section perpendicular to the stacking direction (e.g., z-direction), the resistance chain structure 930 partially surrounds the plurality of memory cells, e.g., the main device region 950. In other words, the resistance chain structure 830 extends over a portion of the circumference of the main device region 950. In other examples, the resistance chain structure 930 extends over several portions of circumference of the main device region 950.

Instead of one circle in FIG. 8 (e.g., one pair of a first and a second resistance pads in a resistance string), FIG. 9 illustrates multiple sets of three circles, each circle indicating a pair of the first and the second resistance pads at the bonding interface 901, e.g., each resistance string includes three pairs of resistance pads. In this way, the other resistance pads could provide the redundancy and better adapt to the requirements for the size or the routing of the semiconductor device. In other examples, one resistance string could include two or more pairs of resistance pads. In some examples, the two or more pairs of resistance pads are arranged side by side. Due to such arrangement, the detection of electrical parameter, such as resistance, is more sensitive. In case that one pair of resistance pads malfunctions, the other pair of resistance pads could still work.

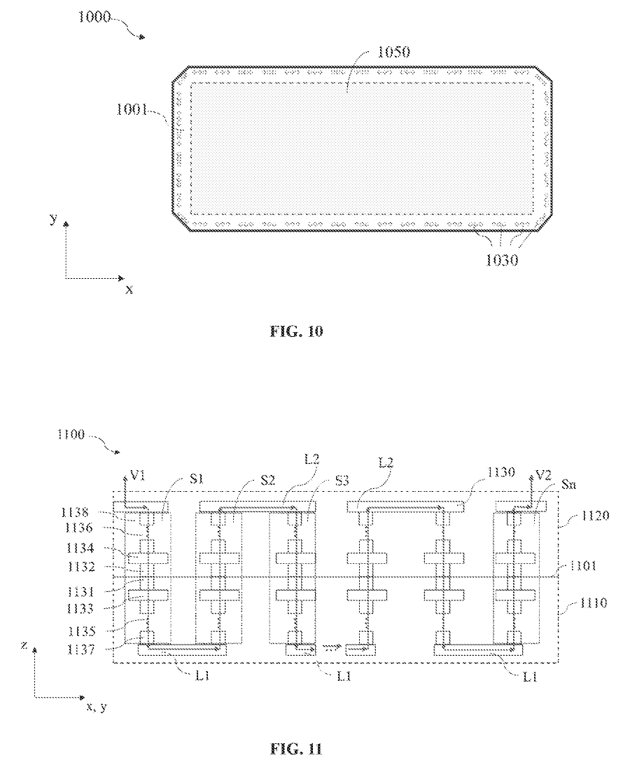

FIG. 10 illustrates yet another example arrangement of the resistance chain structure 1030 in a semiconductor device 1000 at the bonding interface 1001. As shown, the resistance chain structure 830 completely surrounds the plurality of memory cells, e.g., the main device region 1050. In other words, the resistance chain structure 830 extends over the entire circumference of the main device region 1050. FIG. 10 further illustrates multiple pairs of three circles, each circle indicating a pair of the first and the second resistance pads at the bonding interface 1001. The examples illustrated in FIG. 10 combine the advantages demonstrated in both FIGS. 8 and 9. Referring to FIGS. 8-10, the resistance chain structures 830, 930, and 1030 are also located at a corner region of the semiconductor device 800, 900, 1000, or even two, three or more corner regions, or even at every corner region. In some examples, the corner region extends in a direction angled with respect to the transverse directions (e.g., x-direction or y-direction). In this way, it allows for better detection of degree of alignment in the semiconductor device.

FIG. 11 illustrates a schematic sectional view of a semiconductor device 1100 along the z-direction. In an example, the semiconductor device 1100 may be arranged in a similar way as the semiconductor device 800 as shown in FIG. 8. In addition, FIG. 11 is not limited to one single side of semiconductor device, but being able to show the plurality of sides thereof. In other words, FIG. 11 may show the semiconductor device as if its respective sides are laid out flat on a vertical surface including the z-direction, just like a cardboard box being laid out flat. Referring to FIG. 11, the first and the second semiconductor structures 1110, 1120 indicated by dashed boxes are bonded at a bonding interface 1101. An example resistance chain structure 1130 may extend across one or several sides of the semiconductor device 1100. The overall length of the resistance chain structure 1130 may be flexibly designed according to the various semiconductor devices.

For example, when a voltage difference is applied across two detection pads, e.g., a voltage V1 applied at a first detection pad and a voltage V2 at a second detection pad, an electrical current indicated by the arrows flows in the resistance chain structure 1130. Then an electrical parameter of the resistance chain structure 1130 may be measured through the two detection pads to determine the degree of alignment of the semiconductor device 1100, such as measuring the resistance or the current across the two detection pads. Although it is illustrated in FIG. 11 that the two detection pads are provided on a side of the second semiconductor structure 1120 away from the first semiconductor structure 1110, in other examples, the two detection pads could also be provided on a side of the first semiconductor structure away from the second semiconductor structure.

As shown in FIG. 11, the resistance chain structure 1130 includes a plurality of resistance strings S1, S2, S3…Sn. The plurality of resistance strings S1, S2, S3…Sn are serially interconnected. In some examples, the plurality of resistance strings S1, S2, S3…Sn may be arranged as parallel in the z-direction. In FIG. 11, for simplicity, some of the resistance strings are illustrated, and the others are omitted. As shown, in some examples, a first resistance string S1 is connected to its adjacent second resistance string S2 by a first connecting line L1 in the first semiconductor structure 1110. The first connecting line L1 extends in a transverse direction, e.g., x-direction or y-direction. Likewise, the second resistance string S2 is connected to its adjacent third resistance string S3 by a second connecting line L2 in the second semiconductor structure 1120. The second connecting line L2 extends in a transverse direction, e.g., x-direction or y-direction. In some examples, the second connecting line L2 may be parallel with the first connecting line L1. Similarly, the third resistance string S3 is connected to its adjacent fourth resistance string by another first connecting line L1, and it continues sequentially in this manner.

In other words, a plurality of first connecting lines L1 in the first semiconductor structure 1110 interconnects two adjacent resistance strings. A plurality of second connecting lines L2 in the second semiconductor structure 1120 interconnects two adjacent resistance strings. As shown in FIG. 11, the second connecting lines L2 are offset relative to the first connecting lines L1 in a transverse direction, e.g., x-direction or y-direction. In such manner, the resistance chain structure 1130 extends in the first and second semiconductor structures alternatingly, e.g., the resistance chain structure 1130 firstly extends in the first semiconductor structure and substantially in the second semiconductor structure, and then returns to the first semiconductor structure and continues in this way.

In some examples, a first end of the first resistance string S1 is connected with a first detection pad, and a second end of the first resistance string S1 opposite to the first end is connected with a first connecting line L1. The first connecting line L1 connects the first resistance string S1 with its adjacent second resistance string S2. A first end of the second resistance string S2 is connected to a second connecting line L2 in the second semiconductor structure 1120, and a second end of the second resistance string S2 opposite to the first end is connected to the same first connecting line L1. The second connecting line L2 further connects the second resistance string S2 with its adjacent third resistance string S3. In this way, the plurality of resistance strings S1, S2, S3…Sn are connected end-to-end. The second connecting line L2 is offset relative to the first connecting line L1 in the x-direction or y-direction. Moreover, a first end of another resistance string (e.g., the resistance string Sn in FIG. 11) is connected with the second detection pad and a second end of the another resistance string opposite to the first end is connected with a first or a second connecting line. In the example in FIG. 11 that the first end of the resistance string Sn is connected with the second detection pad, its second end opposite to the first end is connected with another first connecting line L1.

In some examples, the plurality of first connecting lines L1 may be provided in the same layer of the first semiconductor structure 1110. Similarly, the plurality of second connecting lines L2 may be provided in the same layer of the second semiconductor structure 1120. The lengths of the first and second connecting lines L1, L2 may be customized according to specific design requirements.

In some examples, each of the plurality of resistance strings S1, S2, S3…Sn may have similar constructions. For simplification, one of these resistance strings is described in this disclosure. Referring to FIG. 11, taking the first resistance string S1 as an example, it includes a pair of a first resistance pad 1131 and a second resistance pad 1132 bonded to the first resistance pad 1131 at the bonding interface 1101. In some examples, the first resistance pad 1131 may be provided in the same layer as the first bonding pad in the first semiconductor structure 1110, e.g., in the first bonding layer aforementioned. In some examples, the second resistance pad 1132 may be provided in the same layer as the second bonding pad in the second semiconductor structure 1120, e.g., in the second bonding layer aforementioned. Further, in some examples, the first resistance pad 1131 may be formed in the same process as the first bonding pad. In some examples, the second resistance pad 1132 may be formed in the same process as the second bonding pad. The alignment deviation between the first and the second resistance pads 1131, 1132 thus reflects the alignment deviation between the first and the second bonding pads.

In some examples, referring to FIG. 11, a first interconnection 1133 in the first semiconductor structure 1110 is connected to the first resistance pad 1131. In an example, the first interconnection 1133 is arranged in a first interconnect layer aforementioned of the first semiconductor structure. In an example in which the first semiconductor structure is a peripheral device chip, the first interconnection 1133 may include a redistribution layer (also referred to as RDL), such as a BEOL top metal redistribution layer. Further, one or more first routing layer(s) 1135 may be connected to the first interconnection 1133. In some examples, the first routing layer 1135 may include a routing metal layer, which may include at least one electrical conductive material, such as Cu, Al, W, Ta, Ti, Co, silicides, or the combination thereof, etc. Another redistribution layer 1137 may be connected to the first routing layer(s) 1135. In an example, another redistribution layer 1137 may be the BEOL bottom metal redistribution layer. The one or more first routing layer(s) 1135 is thus arranged between the BEOL top metal redistribution layer and the BEOL bottom metal redistribution layer.

Still referring to FIG. 11, a second interconnection 1134 in the second semiconductor structure 1120 is connected to the second resistance pad 1132. In an example in which the second semiconductor structure is a memory array chip, the second interconnection 1134 may include a RDL, such as a BEOL top metal redistribution layer. Similarly, one or more second routing layer(s) 1136 may be connected to the second interconnection 1134. In some examples, the second routing layer 1136 may include a routing metal layer, which may include at least one electrically conductive material, such as Cu, Al, W, Ta, Ti, Co, silicides or the combination thereof, etc. Moreover, a metal layer 1138 for circuit lead-out may be connected to the second routing layer 1136. As shown, in an example, a detection pad may be connected to the metal layer 1138.

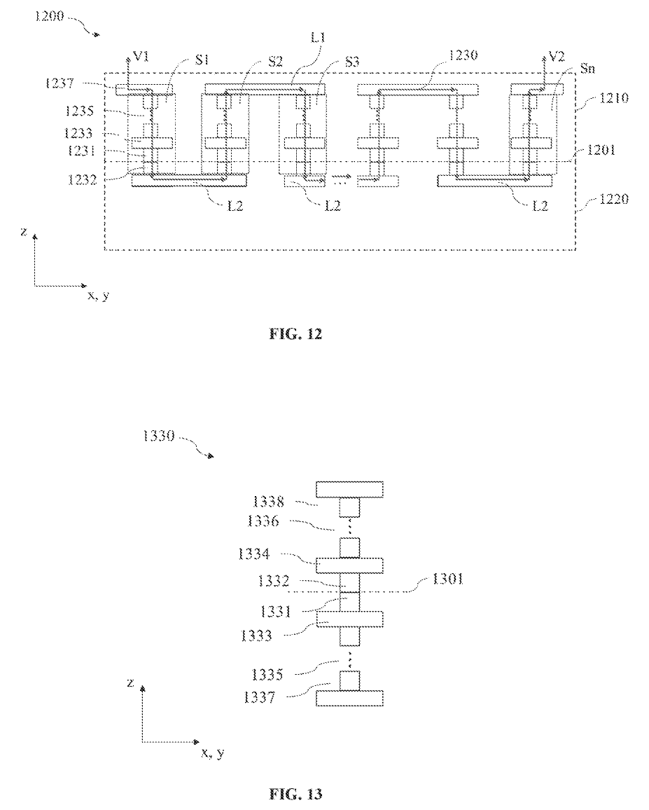

FIG. 12 illustrates another routing of a resistance chain structure 1230 in a semiconductor device 1200. As shown in FIG. 12, the upper and the lower positions of the first and the second semiconductor structures may be reversed. In FIG. 12, the first semiconductor structure 1210 is stacked on the second semiconductor structure 1220, and bonded thereto at a bonding interface 1201. Similar to FIG. 11, the resistance chain structure 30 includes a plurality of resistance strings S1, S2, S3…Sn, which are serially interconnected by means of a plurality of first and second connecting lines L1, L2. Each resistance string includes a pair of a first resistance pad 1131 and a second resistance pad 1132. In the example of FIG. 12, the second connecting line L2 may be directly connected to the second resistance pad 1232. The respective layers 1233, 1235, and 1237 may be similar to those of the corresponding layers 1133, 1135, and 1137 as discussed in the above. As shown in FIG. 12, the first and the second detection pads could also be provided in the first semiconductor structure 1210 on a side away from the second semiconductor structure 1220.

FIG. 13 illustrates a portion of an example resistance chain structure 1330. The resistance string of the resistance chain structure 1330 includes a pair of a first resistance pad 1331 and a second resistance pad 1332 bonded to the first resistance pad 1331 at the bonding interface 1301. The respective layers 1333, 1335, and 1337 are similar to the corresponding layers 1133, 1135, and 1137 as discussed in connection with FIG. 11. Likewise, the respective layers 1334, 1336, and 1338 are similar to the corresponding layers 1134, 1136, 1138 in FIG. 11.

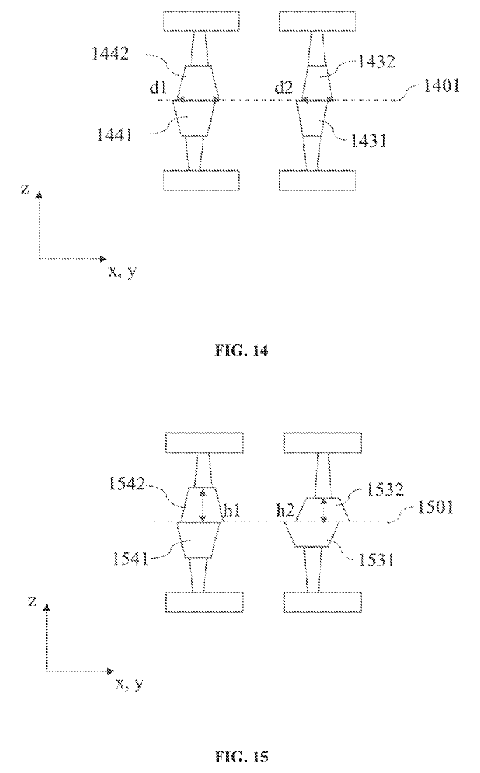

FIG. 14 illustrates the dimensions of the bonding pads and the resistance pads. Referring to FIG. 14, the first bonding pad 1441 is bonded to the second bonding pad 1442 at a bonding interface 1401. The first and/or the second bonding pad have a dimension d1 in a cross section perpendicular to the stacking direction, e.g., in the transverse direction. The first and the second bonding pads may be any of the plurality of pairs of the bonding pads which are bonded during the bonding process. In an example, the first and the second bonding pads 1441, 1442 may be Damascus structure. In an example, the first and the second bonding pads 1441, 1442 may be formed by single Damascene process or dual Damascene process.

In an example, the first and the second resistance pads 1431, 1432 may be Damascus structure. In an example, the first and the second resistance pads 1431, 1432 may be formed by single Damascene process or dual Damascene process. The first resistance pad 1431 is bonded to the second resistance pad 1432 at the same bonding interface 1401. The first and the second resistance pads may have same or similar dimensions. The first and/or the second resistance pads 1431, 1432 have a dimension d2 in the same cross section, which is smaller than the dimension d1. In this way, the pair of the resistance pads may be more sensitive to the electrical parameters, e.g., the current or the resistance, allowing for more precise detection of alignment deviation.

In some examples, the dimension d1 of the first and/or the second resistance pads are in the range of 300-400 nm, or in the range of 310-380 nm, or in the range of 330-380 nm, or even in the range of 340-370 nm. In an example, the dimension d1 of the first and/or the second resistance pads is approximately 335 nm. In an example, the dimension d1 of the first and/or the second resistance pads is approximately 350 nm. The dimension of the resistance pads is provided in this way such that the resistance pads may be easily etched in the etching process, while allowing for improving the reliability of the alignment detection and reducing the ratio of overkill by means of the resistance chain structure.

FIG. 15 illustrates a pair of bonding pads 1541, 1542 and a pair of resistance pads 1531, 1532 which are bonded at a bonding interface 1501. The pair of bonding pads 1541, 1542 has a via with dimension h1 in the stacking direction (e.g., z-direction). The pair of the resistance pads 1531, 1532 has a via with dimension h2 in the stacking direction, which is smaller than the dimension h1. In this way, the pair of the resistance pads may be more sensitive to the electrical parameters, e.g., the current or the resistance, allowing for more precise detection of alignment deviation. The vias of the bonding pads and the resistance pads are filled with metallic conductive materials, such as Cu, W, Al, Ta, Ti, and Co, etc.

FIG. 16 illustrates a schematic flowchart of a method 1600 for manufacturing a semiconductor device in accordance with an example of the present disclosure. The method 1600 includes a step 1610 of forming a first semiconductor structure including a plurality of first resistance pads. The method 1600 includes a step 1620 of forming a second semiconductor structure including a plurality of second resistance pads. In some examples, the step 1610 and the step 1620 may be performed concurrently. The method further includes a step 1630 of stacking and bonding the second semiconductor structure on the first semiconductor in the stacking direction (z-direction), during which the plurality of second resistance pads are bonded to the plurality of first resistance pads respectively. The method 1600 may further include other steps not illustrated in FIG. 16.

In an example, the method 1600 for manufacturing a semiconductor device further includes forming a sealing structure surrounding the first and the second semiconductor structures. During the bonding, a resistance chain structure as discussed above in detail is formed and located on an inner side of the sealing structure.

In an example, the method 1600 for manufacturing a semiconductor device further includes forming a plurality of memory cells. During the bonding of the first and the second semiconductor structures, a resistance chain structure as discussed above in detail is formed and located on an outer side of the plurality of memory cells.

In some examples, forming a plurality of first resistance pads of the resistance chain structure may be in the same process with forming a plurality of first bonding pads in the first semiconductor structure. In some examples, forming a plurality of second resistance pads may be in the same process as forming a plurality of second bonding pads in the second semiconductor structure. In other words, the formation of the first or the second resistance pads may be integrated or combined into the formation of the first or the second bonding pad, respectively.

The resistance chain structure extends in the first and the second semiconductor structures alternatingly and includes a plurality of resistance strings. The plurality of resistance strings in the resistance chain structure are serially interconnected. Each of the plurality of resistance string includes a pair of a first resistance pad of the plurality of first resistance pads and a second resistance pad of the plurality of second resistance pads bonded to the first resistance pad.

In some examples, the step 1610 includes forming first interconnections connected to the plurality of first resistance pad. In some examples, forming first interconnections of the resistance chain structure may be in the same process as forming the interconnections in the first semiconductor structure. In some examples, the step 1620 includes forming second interconnections connected to the plurality of second resistance pad. In some examples, forming second interconnections of the resistance chain structure may be in the same process as that of the interconnections in the second semiconductor structure. In other words, the formation of the first or the second interconnections may be integrated or combined into the formation of the interconnections in the first or the second semiconductor structure, respectively.

In some examples, the step 1610 includes forming first connecting lines in the first semiconductor structure. The first connecting lines interconnect two adjacent resistance strings in the first semiconductor structure. In some examples, the step 1620 includes forming second connecting lines in the second semiconductor structure. The second connecting lines interconnect two adjacent resistance strings in the second semiconductor structure. The second connecting lines are offset relative to the first connecting lines in a transverse direction perpendicular to the stacking direction, respectively.

In some examples, the step 1610 includes forming a first and a second detection pads in the first semiconductor structure. In some examples, the step 1620 includes forming first and second detection pads in the second semiconductor structure. The first and the second detection pads are configured to measure an electrical parameter of the resistance chain structure.

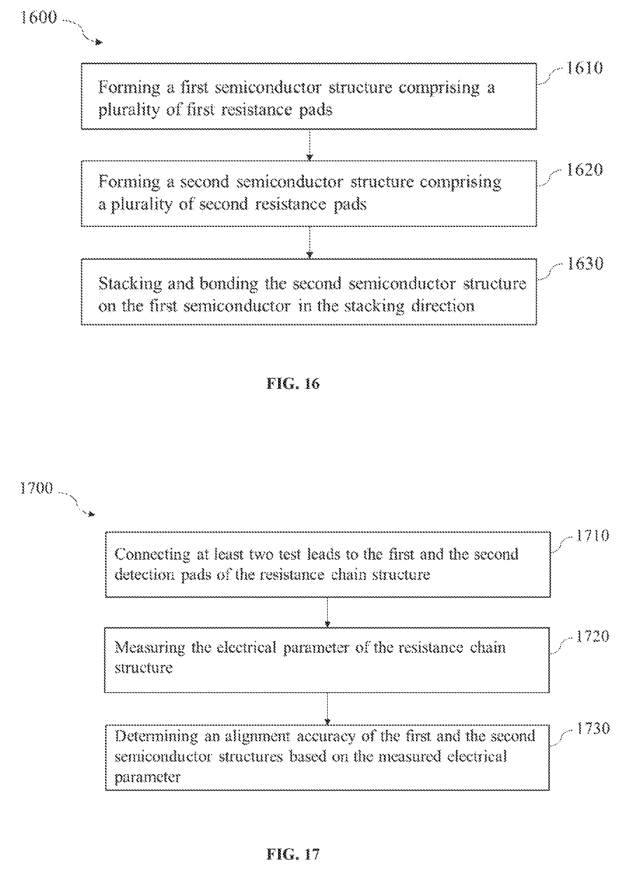

FIG. 17 illustrates a schematic flowchart of a method 1700 for detecting an alignment accuracy in any semiconductor device as discussed in above. The method 1700 includes a step 1710 of connecting at least two test leads to the first and the second detection pads of the resistance chain structure and the step 1720 of measuring the electrical parameter of the resistance chain structure. The method 1700 further includes a step 1730 of determining an alignment accuracy of the first and the second semiconductor structures based on the measured electrical parameter. Due to such method, the alignment accuracy may be easily and precisely determined, thus improving the reliability and sensitivity. Further, the alignment accuracy may be determined chip by chip, or die by die. In other words, instead of the detection for the entire wafer in related approaches, the detection may be performed for individual dies on the wafer, allowing significantly reducing the number of chips or dies mistakenly detected and/or discarded, saving the cost and improving the efficiency. In this manner, the yield rate is thus improved. The method 1700 may further include other steps not illustrated in FIG. 17.

In some examples, the method for detecting an alignment accuracy further includes establishing a correlation between the electrical parameter (such as current or resistance) and the alignment accuracy of the first and the second semiconductor structures. In some examples, the method for detecting an alignment accuracy further includes determining the alignment accuracy based on the correlation and the measured electrical parameter. In some examples, the correlation between the electrical parameter and the alignment accuracy is also based on Defective Parts Per Million (usually referred to as DPPM) test.

In some examples, the method for detecting an alignment accuracy includes determining a threshold of the electrical parameter corresponding to an acceptable alignment accuracy and comparing the measured electrical parameter to the threshold to determine whether the alignment accuracy is acceptable. For example, with respect to the same semiconductor device, the acceptable threshold range of the resistance corresponding to the acceptable alignment accuracy is predetermined. By measuring the resistance using the present technique(s), it may be possible to determine whether the alignment accuracy is acceptable with a greater degree of accuracy than other methods.

In some examples, the semiconductor device includes a plurality of memory cells. The method for detecting an alignment accuracy includes forming a resistance chain structure located on an outer side of the plurality of memory cells, with a similar construction as mentioned in above. The method for detecting an alignment accuracy further includes connecting at least two test leads to the first and the second detection pads of the resistance chain structure and measuring the electrical parameter of the resistance chain structure. The method for detecting an alignment accuracy further includes determining an alignment accuracy of the first and the second semiconductor structures based on the measured electrical parameter.

In some examples, the method for detecting an alignment accuracy may be performed several times and the measured electrical parameters may be averaged for determining the alignment accuracy. In some examples, the method for detecting an alignment accuracy may be performed at different locations.

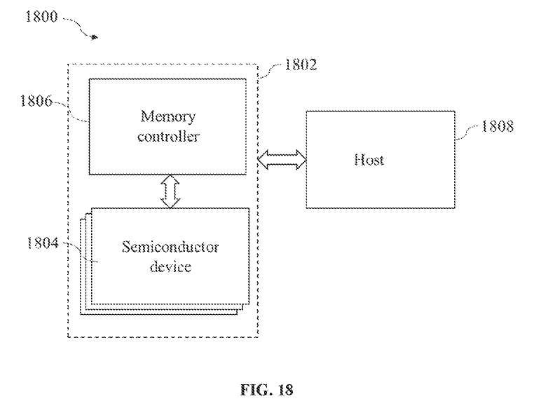

FIG. 18 is a schematic diagram of an electronic device 1800 illustrated according to examples of the present disclosure. Referring to FIG. 18, the electronic device 1800 may include a host 1808 and a memory system 1802 having one or more semiconductor devices 1804 and a memory controller 1806. Host 1808 may be configured to send or receive the data to or from semiconductor devices 1804.

Semiconductor device 1804 may be any semiconductor devices disclosed herein, such as a 3D memory device. In some examples, each semiconductor device 1804 includes one or more memory cell arrays and one or more peripheral circuits of the memory cell arrays. In some examples, semiconductor device 1804 may be any suitable memory device including, but not limited to read-only memory (ROM) device, random access memory (RAM) device, magnetic disk memory device, optical memory device, flash memory device, dynamic flash memory (DFM) device, etc.

Memory controller 1806 is coupled to semiconductor device 1804 and host 1808, and is configured to control semiconductor device 1804, according to some examples. Memory controller 1806 may manage the data stored in semiconductor device 1804 and communicate with host 1808. In some examples, memory controller 1806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some examples, memory controller 1806 is designed for operating in a high duty-cycle environment SSDs or embedded multi-media-cards (eMMCs) used as data storage for mobile devices, such as smartphones, tablets, laptop computers, etc., and enterprise storage arrays.

Memory controller 1806 may be configured to control operations of semiconductor device 1804, such as read, erase, and program operations. In some examples, memory controller 1806 is configured to control the array of memory cells through the peripheral circuit. Memory controller 1806 may also be configured to manage various functions with respect to the data stored or to be stored in semiconductor device 1804 including, but not limited to bad-block management, garbage collection, logical-to-physical address conversion, wear leveling, etc. In some examples, memory controller 1806 is further configured to process error correction codes (ECCs) with respect to the data read from or written to semiconductor device 1804. Any other suitable functions may be performed by memory controller 1806 as well, for example, formatting semiconductor device 1804.

Memory controller 1806 may communicate with an external device (e.g., host 1808) according to a particular communication protocol. For example, memory controller 1806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1806 and one or more semiconductor devices 1804 may be integrated into various types of storage devices, for example, be included in the same package, such as a universal Flash storage (UFS) package or an eMMC package. That is, memory system 1802 may be implemented and packaged into different types of end electronic products.

While several examples have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the examples described herein. More generally, those skilled in the art will readily appreciate that all parameters, dimensions, materials, and configurations described herein are meant to be example and that the actual parameters, dimensions, materials, and/or configurations will depend upon the specific application or applications for which the teachings is/are used. Those skilled in the art will recognize, or be able to ascertain using no more than routine experimentation, many equivalents to the specific examples described herein. It is, therefore, to be understood that the foregoing examples are presented by way of example, and within the scope of the appended claims and equivalents thereto, examples may be practiced other than as specifically described and claimed. Examples of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. A semiconductor device, comprising:
a first semiconductor structure;
a second semiconductor structure stacked on the first semiconductor structure in a stacking direction and bonded thereto;
a sealing structure surrounding the first and the second semiconductor structures; and
a resistance chain structure located on an inner side of the sealing structure, wherein the resistance chain structure extends in the first and second semiconductor structures alternatingly and comprises a plurality of first resistance pads in the first semiconductor structure and a plurality of second resistance pads in the second semiconductor structure, the plurality of second resistance pads being bonded to the plurality of first resistance pads respectively.

2. The semiconductor device of claim 1, further comprising:
a plurality of memory cells located on an inner side of the resistance chain structure.

3. The semiconductor device of claim 1, wherein the sealing structure comprises an isolation structure.

4. The semiconductor device of claim 2, further comprising:
a test structure located between the resistance chain structure and the plurality of memory cells.

5. The semiconductor device of claim 2, wherein in a cross section perpendicular to the stacking direction, the resistance chain structure completely or partially surrounds the plurality of memory cells.

6. The semiconductor device of claim 5, wherein the resistance chain structure is further located at a corner region of the semiconductor device.

7. The semiconductor device of claim 1, wherein the resistance chain structure comprises a plurality of resistance strings, the plurality of resistance strings in the resistance chain structure are serially interconnected,
wherein a resistance string of the plurality of resistance strings comprises a pair of a first resistance pad of the plurality of first resistance pads and a second resistance pad of the plurality of second resistance pads bonded to the first resistance pad.

8. The semiconductor device of claim 7, wherein the resistance string further comprises:
first interconnections arranged in the first semiconductor structure and connected to the first resistance pad; and
second interconnections arranged in the second semiconductor structure and connected to the second resistance pad.

9. The semiconductor device of claim 8, wherein
the first interconnections are arranged in a first interconnect layer of the first semiconductor structure; and
the second interconnections are arranged in a second interconnect layer of the second semiconductor structure.

10. The semiconductor device of claim 7, wherein the resistance chain structure further comprises:
first connecting lines interconnecting two adjacent resistance strings in the first semiconductor structure; and
second connecting lines interconnecting two adjacent resistance strings in the second semiconductor structure, wherein the second connecting lines are offset relative to the first connecting lines in a transverse direction perpendicular to the stacking direction.

11. The semiconductor device of claim 10, wherein a first connecting line connects a first resistance string with a second resistance string adjacent to the first resistance string, a second connecting line connects the second resistance string with a third resistance string adjacent to the second resistance string, and the second connecting line is offset relative to the first connecting line in the transverse direction.

12. The semiconductor device of claim 1, wherein:
the second semiconductor structure is bonded to the first semiconductor structure via a plurality of pairs of bonding pads, and
at least one of the plurality of first resistance pads or the plurality of second resistance pads has a dimension in a cross section perpendicular to the stacking direction which is smaller than that of a bonding pad of the plurality of pairs of bonding pads.

13. The semiconductor device of claim 12, wherein a dimension in a cross section perpendicular to the stacking direction of the plurality of first resistance pads or the plurality of second resistance pads is in a range of 300-400 nm.

14. The semiconductor device of claim 12, wherein at least one of the plurality of first resistance pads or the plurality of second resistance pads has a via with a dimension in the stacking direction which is smaller than that of a bonding pad of the plurality of pairs of bonding pads.

15. The semiconductor device of claim 1, wherein the resistance chain structure comprises a first and a second detection pads configured to measure an electrical parameter of the resistance chain structure, and the first and second detection pads are located on a side of the first or second semiconductor structure away from each other.

16. The semiconductor device of claim 15, wherein a first end of one resistance string is connected with the first detection pad and a second end of the one resistance string opposite to the first end is connected with a first or a second connecting line; and
a first end of another resistance string is connected with the second detection pad and a second end of the another resistance string opposite to the first end is connected with a first or a second connecting line.

17. The semiconductor device of claim 1, wherein:
the plurality of first resistance pads are arranged in a first bonding layer of the first semiconductor structure; and
the plurality of second resistance pads are arranged in a second bonding layer of the second semiconductor structure.

18. A semiconductor device, comprising:
a first semiconductor structure;
a second semiconductor structure stacked on the first semiconductor structure in a stacking direction and bonded thereto;
a plurality of memory cells; and
a resistance chain structure located on an outer side of the plurality of memory cells, wherein the resistance chain structure extends in the first and second semiconductor structures alternatingly and comprises a plurality of first resistance pads in the first semiconductor structure and a plurality of second resistance pads in the second semiconductor structure, the plurality of second resistance pads being bonded to the plurality of first resistance pads respectively.

19. The semiconductor device of claim 18, further comprising:
a test structure located on an outer side of the resistance chain structure.

20. A method for detecting an alignment accuracy in a semiconductor device, comprising:
forming a resistance chain structure, wherein the resistance chain structure extends in a first semiconductor structure and a second semiconductor structure alternatingly and comprises a plurality of first resistance pads in the first semiconductor structure and a plurality of second resistance pads in the second semiconductor structure, the plurality of second resistance pads being bonded to the plurality of first resistance pads, respectively, wherein the resistance chain structure further comprises a first and a second detection pads configured to measure an electrical parameter of the resistance chain structure, and wherein the semiconductor device comprises the first semiconductor structure, the second semiconductor structure stacked on the first semiconductor structure in a stacking direction and bonded thereto and a sealing structure surrounding the first and the second semiconductor structures;
connecting at least two test leads to the first and the second detection pads of the resistance chain structure and measuring the electrical parameter of the resistance chain structure; and
determining an alignment accuracy of the first and the second semiconductor structures based on the measured electrical parameter.
